(19) United States
(12) Patent Application Publication
(10) Pub. No.: US 2025/0330127 A1
(43) Pub. Date: Oct. 23, 2025

(54) INCREASED POWER EFFICIENCY IN DOHERTY POWER AMPLIFIERS USING DOUBLE HARMONIC GATE TERMINATIONS

(71) Applicant: SKYWORKS SOLUTIONS, INC., Irvine, CA (US)

(72) Inventor: Jun Celis Jadormio, Marlborough, MA (US)

(21) Appl. No.: 19/097,714

(22) Filed: Apr. 1, 2025

Related U.S. Application Data
(60) Provisional application No. 63/572,410, filed on Apr. 1, 2024.

(51) Int. Cl. H03F 1/02; H03F 1/56; H03F 3/24

(52) U.S. Cl. CPC H03F 1/0288; H03F 1/56; H03F 3/245; H03F 2200/391; H03F 2200/451

(57) ABSTRACT

Double harmonic gate terminations are used to increase power efficiency in Doherty power amplifiers. These technologies increase power efficiency in Doherty power amplifiers through wave shaping using double harmonic gate terminations. The double harmonic gate terminations span a targeted input frequency range over which the power amplifiers operate. The double harmonic gate terminations cover a wider bandwidth than a single harmonic gate termination. The harmonic termination can include more than two terminations to cover a broader range of frequencies or to cover a wider bandwidth. It may be desirable to implement the broad harmonic gate termination using two gate terminations to keep the size of the circuit and module small and to reduce costs relative to other solutions for harmonic gate terminations that utilize a greater number of components or components of a larger size.

### CROSS-REFERENCE TO RELATED APPLICATIONS

This application claims priority to U.S. Provisional Application No. 63/572,410 filed Apr. 1, 2024 and entitled “INCREASE POWER EFFICIENCY IN DOHERTY POWER AMPLIFIERS USING DOUBLE HARMONIC GATE TERMINATIONS,” which is expressly incorporated by reference herein in its entirety for all purposes.

### BACKGROUND

### Field

The present disclosure generally relates to Doherty power amplifier configurations.

### Description of Related Art

Wireless devices employ a variety of amplifiers to amplify signals. These wireless devices employ power amplifiers to amplify signals prior to transmission. A variety of power amplifier architectures may be employed. One example is a Doherty power amplifier which may be particularly beneficial in wireless devices with high peak to average power ratio (PAPR) modulation signals.

### SUMMARY

According to a number of implementations, the present disclosure relates to a Doherty power amplifier for amplifying radio-frequency (RF) signals with an input frequency range corresponding to a system bandwidth. The Doherty power amplifier includes a power splitter configured to receive an input signal and to provide a first signal associated with the input signal on a carrier amplification path and a second signal associated with the input signal on a peaking amplification path; a first impedance matching network implemented on the carrier amplification path; a carrier amplifier implemented on the carrier amplification path; a double harmonic termination circuit implemented on the carrier amplification path between the first impedance matching network and the carrier amplifier, the double harmonic termination circuit configured to short a range of second harmonics for the system bandwidth; and a peaking amplifier implemented on the peaking amplification path.

In some implementations, the system bandwidth is greater than or equal to 400 MHZ.

In some implementations, the double harmonic termination circuit includes exactly two LC network circuits in parallel. In some implementations, the Doherty power amplifier further includes a common mode ground inductor coupled in series between the two LC network circuits and a reference potential node. In some implementations, a first LC network circuit of the two LC network circuits is configured to resonate between a second harmonic frequency of a low end frequency of the input frequency range and a second harmonic frequency of a center band frequency of the input frequency range. In some implementations, a second LC network circuit of the two LC network circuits is configured to resonate between the second harmonic frequency of the center band frequency and a second harmonic frequency of a high end frequency of the input frequency range.

In some implementations, the double harmonic termination circuit includes more than two LC network circuits in parallel. In some implementations, the Doherty power amplifier further includes a second impedance matching network implemented on the peaking amplification path between the power splitter and the peaking amplifier.

In some implementations, the carrier amplifier comprises a transistor. In some implementations, the double harmonic termination circuit is coupled between a base of the transistor and a reference potential node.

According to a number of implementations, the present disclosure relates to a front end module that includes a packaging substrate; and a Doherty power amplifier implemented on the packaging substrate, the Doherty power amplifier configured to amplify radio-frequency (RF) signals in an input frequency range corresponding to a system bandwidth, the Doherty power amplifier including: a power splitter configured to receive an input signal and to provide a first signal associated with the input signal on a carrier amplification path and a second signal associated with the input signal on a peaking amplification path; a first impedance matching network implemented on the carrier amplification path; a carrier amplifier implemented on the carrier amplification path; a double harmonic termination circuit implemented on the carrier amplification path between the first impedance matching network and the carrier amplifier, the double harmonic termination circuit configured to short a range of second harmonics for the input frequency range; and a peaking amplifier implemented on the peaking amplification path.

In some implementations, the system bandwidth is greater than or equal to 400 MHZ.

In some implementations, the double harmonic termination circuit includes exactly two LC network circuits in parallel. In some implementations, the front end module further includes a common mode ground inductor coupled in series between the two LC network circuits and a reference potential node.

In some implementations, a first LC network circuit of the two LC network circuits is configured to resonate between a second harmonic frequency of a low end frequency of the input frequency range and a second harmonic frequency of a center band frequency of the input frequency range. In some implementations, a second LC network circuit of the two LC network circuits is configured to resonate between the second harmonic frequency of the center band frequency and a second harmonic frequency of a high end frequency of the input frequency range.

In some implementations, the double harmonic termination circuit includes more than two LC network circuits in parallel. In some implementations, the front end module further includes a second impedance matching network implemented on the peaking amplification path between the power splitter and the peaking amplifier. In some implementations, the carrier amplifier comprises a transistor and the double harmonic termination circuit is coupled between a base of the transistor and a reference potential node.

According to a number of implementations, the present disclosure relates to a wireless device that includes a primary antenna; and a front end module coupled to the primary antenna, the front end module comprising a Doherty power amplifier configured to amplify radio-frequency (RF) signals in an input frequency range corresponding to a system bandwidth, the Doherty power amplifier including: a power splitter configured to receive an input signal and to provide a first signal associated with the input signal on a carrier amplification path and a second signal associated with the input signal on a peaking amplification path; a first impedance matching network implemented on the carrier amplification path; a carrier amplifier implemented on the carrier amplification path; a double harmonic termination circuit implemented on the carrier amplification path between the first impedance matching network and the carrier amplifier, the double harmonic termination circuit configured to short a range of second harmonics for the input frequency range; and a peaking amplifier implemented on the peaking amplification path.

For purposes of summarizing the disclosure, certain aspects, advantages and novel features have been described herein. It is to be understood that not necessarily all such advantages may be achieved in accordance with any particular embodiment. Thus, the disclosed embodiments may be carried out in a manner that achieves or optimizes one advantage or group of advantages as taught herein without necessarily achieving other advantages as may be taught or suggested herein.

### BRIEF DESCRIPTION OF THE DRAWINGS

FIG. 1 illustrates a wireless device having a primary antenna with amplifiers that use the technologies disclosed herein.

FIG. 2 illustrates a Doherty power amplifier architecture that implements a broad harmonic termination circuit to reduce intermodulation distortion in the carrier amplifier.

FIG. 3 illustrates a traditional Doherty power amplifier architecture that implements a single harmonic gate termination circuit.

FIG. 4A illustrates a Doherty power amplifier architecture that implements a double harmonic gate termination circuit.

FIG. 4B illustrates a Doherty power amplifier architecture that implements a termination circuit with a plurality of harmonic gates.

FIG. 5 illustrates a Smith chart of the reflection coefficients at the base of the transistor Q1 of FIGS. 3, 4A, and 4B over the frequency range 6.8 GHz to 7.6 GHz for the single harmonic termination.

FIG. 6 illustrates a Smith chart over the same frequency range as FIG. 5 for the reflection coefficients for the double harmonic termination.

FIG. 7 illustrates a graph of the power added efficiency of the single harmonic termination (dashed line) and the double harmonic termination (solid line).

FIG. 8 illustrates that some or all of the front end configurations with Doherty power amplifier configurations described herein can be implemented in a module.

FIG. 9 illustrates that some or all of the front end configurations with Doherty power amplifier configurations described herein can be implemented in an architecture.

FIG. 10 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

### Overview

Radio-frequency (RF) applications, such as those implemented in wireless devices, typically use power amplifiers to amplify signals prior to transmission. There exist various power amplifier architectures that may be implemented for such devices. For example, Doherty power amplifier (PA) applications are particularly suited for high peak to average power ratio (PAPR) modulation signals used in various wireless devices (e.g., smart phones and cellular phones). Doherty power amplifiers can provide certain advantages over other designs, such as achieving up to about 10% higher peak power added efficiency (PAE) levels for the same adjacent power level ratio (ACLR) levels. This level of PAE performance can match that of an envelope tracking (ET) PA but with less overall system complexity than for ET PAs.

However, non-linearity and intermodulation distortions can reduce the quality of signals amplified using Doherty power amplifiers. Traditionally, a harmonic gate termination can be used on one of the Doherty PA branches to short harmonic signals to ground to increase the amplifier efficiency or PAE. These approaches typically use a single LC circuit as the harmonic gate termination. However, this is not suitable for applications where the RF signals to be amplified cover a relatively large input frequency range or bandwidth (e.g., wideband applications with a bandwidth that is greater than or equal to about 400 MHZ). As described herein, harmonic termination can be improved for wideband applications where the disclosed solutions are sufficiently simple so as to not adversely affect the size and complexity of the modules incorporating the disclosed Doherty PAs.

Accordingly, described herein are technologies to increase power efficiency in Doherty power amplifiers using double harmonic gate terminations. The disclosed techniques are configured to increase or maximize power efficiency in Doherty power amplifiers through wave shaping using double harmonic gate terminations. The disclosed double harmonic gate terminations can be configured to span a targeted input frequency range over which the disclosed power amplifiers are configured to operate. In some implementations, the disclosed double harmonic gate terminations cover a wider bandwidth than a single harmonic gate termination. In some implementations, the harmonic termination can include more than two terminations to cover a broader range of frequencies or to cover a wider bandwidth. In certain implementations, it is desirable to implement the broad harmonic gate termination using two gate terminations to keep the size of the circuit and module small and to reduce costs relative to other solutions for harmonic gate terminations that utilize a greater number of components or components of a larger size. The disclosed technologies can be applied to different semiconductor technologies (e.g., CMOS, GaAs, LDMOSFET, and GaN).

Front End Modules with Doherty PAs Using Double Harmonic Gate Terminations

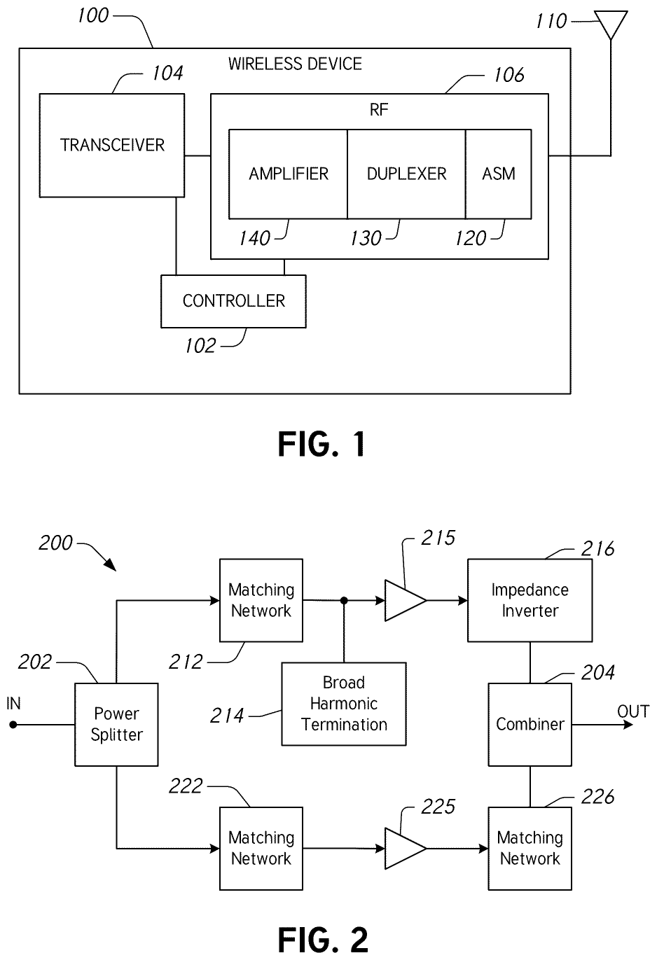

FIG. 1 illustrates a wireless device 100 having a primary antenna 110 with amplifiers 140 that use the technologies disclosed herein. The wireless device 100 includes an RF module 106 and a transceiver 104 that may be controlled by a controller 102. The transceiver 104 is configured to convert between analog signals (e.g., radio-frequency (RF) signals) and digital data signals. To that end, the transceiver 104 may include a digital-to-analog converter, an analog-to-digital converter, a local oscillator for modulating or demodulating a baseband analog signal to or from a carrier frequency, a baseband processor that converts between digital samples and data bits (e.g., voice or other types of data), or other components.

The RF module 106 is coupled between the primary antenna 110 and the transceiver 104. Because the RF module 106 may be physically close to the primary antenna 110 to reduce attenuation due to cable loss, the RF module 106 may be referred to as a front end module (FEM). The RF module 106 may perform processing on an analog signal received from the primary antenna 110 for the transceiver 104 or received from the transceiver 104 for transmission via the primary antenna 110. To that end, the RF module 106 includes an antenna switch module 120 (ASM), one or more duplexers 130, one or more amplifiers 140 (including power amplifiers (PAs) and low noise amplifiers (LNAs)) and may also include band select switches, attenuators, matching circuits, and other components. The ASM 120 may be connected to a plurality of duplexers 130 to enable operation across a plurality of frequency bands. The RF module 106 provides a receive path for signals received at the primary antenna 110, the receive path including a signal path from the primary antenna 110, to the ASM 120, to the duplexers 130, to the amplifiers 140, to the transceiver 104. Similarly, the RF module 106 provides a transmit path for signals to be transmitted by the primary antenna 110, the transmit path including a signal path from the transceiver 104, to the amplifiers 140, to the duplexers 130, to the ASM 120, and to the primary antenna 110 for transmitting.

The controller 102 can be configured to generate and/or send control signals to other components of the wireless device 100. The controller 102 can be configured to receive signals from other components of the wireless device 100 to process to determine control signals to send to other components. In some embodiments, the controller 102 can be configured to analyze signals or data to determine control signals to send to other components of the wireless device 100.

The RF module 106 is an example of a front end module that incorporates the front end architectures described herein, and particular the Doherty PA architectures disclosed herein. These Doherty PA architectures include broad harmonic terminations to reduce intermodulation distortions in at least one branch of the Doherty PA. Characteristics of the amplifiers 140, duplexers 130, and ASM 120 can be tailored to improve amplifier performance, including by reducing harmonics in the amplified signal through the use of harmonic terminations, as described herein. In addition, impedance matching components along the receive path may also be tailored to improve amplifier performance.

Example Doherty Power Amplifier Architecture with Broad Harmonic Termination

FIG. 2 illustrates a Doherty PA architecture 200 that implements a broad harmonic termination circuit 214 to reduce intermodulation distortion in the carrier amplifier 215. The Doherty PA architecture 200 includes two amplifier paths, both fed from a power splitter 202. The carrier amplifier 215 is always on while the peaking amplifier 225 remains idle unless the signal moves into a high-power region. In the high-power region, the peaking amplifier 225 turns on and provides additional amplification to support the higher output power. After amplification, the amplified signals are combined at the combiner 204. In addition, there is a first impedance matching network 212 between the carrier amplifier 215 and the power splitter 202, a second impedance matching network 222 between the peaking amplifier 225 and the power splitter 202, and a third impedance matching network 226 between the peaking amplifier 225 and the combiner 204. The Doherty PA architecture 200 also includes an impedance inverter 216 between the carrier amplifier 215 and the combiner 204. The impedance inverter 216 can be implemented as a quarter-wave transmission line to provide an impedance inversion at the output of the carrier amplifier 215. This can be done to align the two amplifier paths, for example.

Many modulation techniques maintain amplitude and phase purity. Therefore, to maintain linearity, the carrier amplifier 215 can be operated in Class A, Class B or Class AB. Similarly, the peaking amplifier 225 can be operated in Class C, meaning that the amplifier is only biased on part of the time. Class C can be associated with non-linear operation but because the Doherty PA architecture 200 incorporates the peaking amplifier 225 as an add-on device, linearity is typically maintained at the output. Although the Doherty PA architecture 200 shows two amplifier paths, some designs can use additional peaking amplifiers to improve performance in the high-power region. In addition, although the various examples are described in the context of a Doherty PA architecture, it will be understood that one or more features of the present disclosure can also be implemented in other types of PA systems.

The Doherty PA architecture 200 is shown to include an input port (IN) for receiving an RF signal to be amplified. Such an input RF signal can be partially amplified by a pre-driver amplifier before being divided into a carrier amplification path and a peaking amplification path. Such a division can be achieved by a divider or a power splitter 202.

The carrier amplification path includes the first impedance matching network 212, the broad harmonic termination circuit 214, the carrier amplifier 215 and the impedance inverter 216. The peaking amplification path includes the second impedance matching network 222, the peaking amplifier 225, and the third impedance matching network 226. In some implementations, the carrier amplifier 215 and/or the peaking amplifier 225 each include one or more amplification stages (e.g., a driver stage and an output stage). As described in greater detail herein, bias circuits can be used to bias the carrier amplifier 215 and/or the peaking amplifier 225. The carrier amplification path and the peaking amplification path can be combined by a combiner 204 so as to yield an amplified RF signal at an output port (OUT).

In some implementations, the carrier amplifier 215 can be configured to operate in a Class AB mode. In some implementations, the peaking amplifier 225 can be configured to operate in a Class B mode. The different biasing modes can include Class A, Class B, Class AB, Class C, Class D, Class F, Class G, Class I, Class S, Class T, or any other biasing mode. In some implementations, the Doherty PA architecture 200 is based on gallium nitride (GaN) technology.

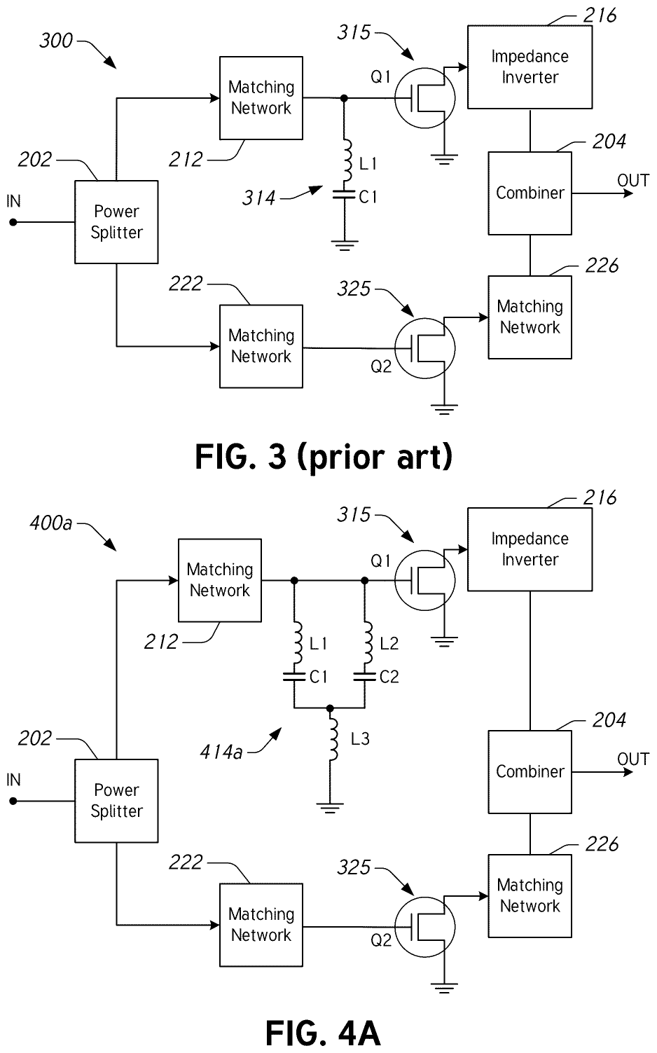

The broad harmonic termination circuit 214 is configured to reduce or eliminate intermodulation distortion, such as second order harmonics, in the amplified signal from the carrier amplifier 215. The broad harmonic termination circuit 214 can include two or more LC circuits that have values configured to provide a short to ground for frequencies within a targeted frequency range. For example, the broad harmonic termination circuit 214 can be a double harmonic gate termination circuit that includes two parallel LC circuits with values that resonate with frequencies between a lower frequency bound and an upper frequency bound. In such instances, the first LC circuit can be between the lower frequency bound and a midpoint between the lower frequency bound and the upper frequency bound. Similarly, the second LC circuit can be between the upper frequency bound and the midpoint between the lower frequency bound and the upper frequency bound. In addition, the double harmonic gate termination circuit can include an additional inductor between the two parallel LC circuits and a reference potential node (such as a ground potential). Thus, the broad harmonic termination circuit 214 is configured to cover a wider bandwidth than a single or narrowband harmonic termination circuit (such as the harmonic termination circuit described herein with respect to FIG. 3).

In various implementations, the broad harmonic termination circuit 214 includes more than two parallel LC circuits. However, this may increase the size, cost, and/or complexity of the Doherty PA architecture 200. Other solutions may be implemented as well, such as with a tunable LC circuit that can change the resonating properties during operation to resonate with a targeted frequency within the targeted frequency range. Similarly, though, this may increase the size, cost, and/or complexity of the Doherty PA architecture 200. An increase in size, cost, and/or complexity may be acceptable in certain implementations. However, in certain implementations in wireless devices, it is desirable to maintain the cost, size, and complexity low. Thus, in such implementations, it may be desirable or advantageous to implement the broad harmonic termination circuit 214 as a double harmonic termination circuit, as described herein.

The Doherty PA architectures disclosed herein increase power added efficiency (PAE) for high peak-to-average ratio (PAPR) applications. The reductions in power dissipation resulting from the disclosed harmonic termination circuits result in an amplifier that delivers higher PAE.

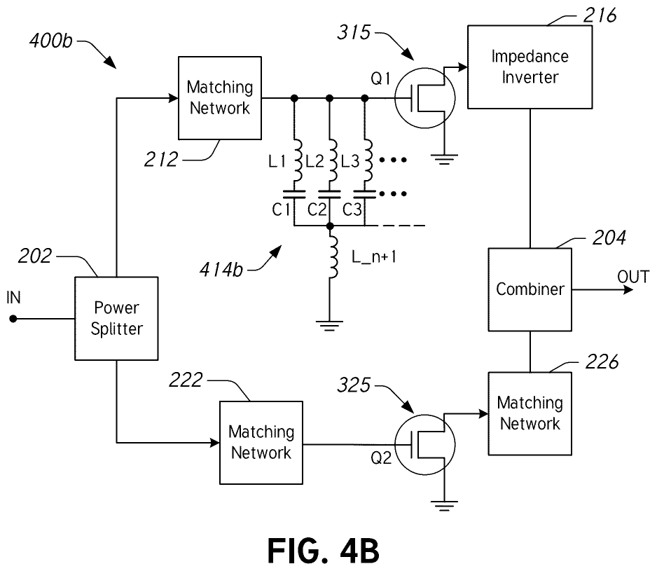

For comparison, FIG. 3 illustrates a traditional GaN Doherty PA architecture 300 that implements a single harmonic gate termination circuit 314 and FIG. 4A illustrates a Doherty PA architecture 400a that implements a double harmonic gate termination circuit 414a. Referring to FIGS. 3 and 4A, both the traditional GaN Doherty PA architecture 300 and the Doherty PA architecture 400a are configured similarly to the Doherty PA architecture 200, namely each architecture includes the power splitter 202, first impedance matching network 212, impedance inverter 216, second impedance matching network 222, third impedance matching network 226, and the combiner 204 as described herein with reference to FIG. 2. Furthermore, both the traditional GaN Doherty PA architecture 300 and the Doherty PA architecture 400a use transistor circuits for the carrier amplifier 315 and the peaking amplifier 325. Thus, a difference between the traditional GaN Doherty PA architecture 300 of FIG. 3 and the Doherty PA architecture 400a of FIG. 4A is the harmonic termination circuits. The traditional GaN Doherty PA architecture 300 includes the single harmonic gate termination circuit 314. The Doherty PA architecture 400a includes the double harmonic gate termination circuit 414a.

The power dissipation of an RF amplifier includes DC power along with the power of the voltage and the current on each frequency being amplified, such as the fundamental signal and harmonics to that signal. Increased or maximum power efficiency is delivered in an amplifier by reducing the power dissipation in the transistor device. To achieve this goal, it is advantageous to transfer the DC power to fundamental power without also amplifying harmonic frequencies.

Aside from proper biasing techniques, typical solutions to improve PAE for maximum power efficiency of an amplifier include implementing a harmonic termination circuit tuned to short second harmonics. Referring to FIG. 3, the single harmonic gate termination circuit 314 for example uses a series LC network circuit (L1 and C1) connected at the gate of transistor (Q1) device. The single harmonic gate termination circuit 314 acts as a resonator that shorts the impedance of the second harmonics. Shorting the second harmonic helps to reduce the power dissipation of the active device to increase the efficiency of the carrier amplifier 315. This is the typical approach when operating the amplifier as a Class A or AB to improve amplifier efficiency. This approach is suitable for a narrow band system because it terminates a single frequency in the second harmonic region. However, for broadband applications (e.g., above about 400 MHz bandwidth), this method does not effectively cover the entire bandwidth.

Referring to FIG. 4A, the Doherty PA architecture 400a implements the double harmonic gate termination circuit 414a that uses two LC network circuits in parallel connected at the gate of the transistor (Q1) device. The double harmonic gate termination circuit 414a acts in a way similar to the single harmonic gate termination circuit 314, it shorts the impedance of second harmonics, but it does so in a way that covers a wider bandwidth. In the double harmonic gate termination circuit 414a, the first harmonic termination series LC network circuit (inductor L1 with capacitor C1) is in parallel with the second harmonic termination series LC network circuit (inductor L2 with capacitor C2). The double harmonic gate termination circuit 414a also includes a common mode inductor L3 coupled between the two series LC network circuits and a reference potential node, such as a ground potential node. The common mode inductor L3 serves as common mode ground inductance. For wider bandwidth response, the first harmonic termination series LC network circuit (L1/C1) is configured to resonate somewhere in between the second harmonic frequency of the lower end frequency and center band frequency while the second harmonic termination series LC network circuit (L2/C2) is configured to resonate somewhere in between the second harmonic frequency of the center band frequency and the higher end frequency. This implementation is configured to terminate multiple frequency points in the harmonic region to cover a wider bandwidth response. That is, the double harmonic gate termination circuit 414a is configured to short the impedance for the second harmonics at lower frequencies and higher frequencies which, when joined together, cover a targeted frequency band. For example, each LC network circuit in the double harmonic gate termination circuit 414a can be configured to cover approximately 200 MHz when the targeted frequency bandwidth is about 400 MHZ. As a particular example, if the harmonics of the input frequency range are between 7 GHz and 7.4 GHz (covering a bandwidth of 400 MHZ), the first LC network circuit is configured to short the second harmonic frequencies between 7.0 GHz and 7.2 GHz while the second LC network circuit is configured to short the second harmonic frequencies between 7.2 GHz and 7.4 GHz.

Advantageously, the Doherty PA architecture 400a with the double harmonic gate termination circuit 414a increases second harmonic termination bandwidth. In addition, the Doherty PA architecture 400a with the double harmonic gate termination circuit 414a improves PAE. In addition, the Doherty PA architecture 400a with the double harmonic gate termination circuit 414a increases product market competitiveness.

The double harmonic gate termination circuit 414a can be modified to include additional LC network circuits to increase the bandwidth covered by the harmonic termination circuit. FIG. 4B illustrates another Doherty PA architecture 400b with a harmonic gate termination circuit 414b that includes two or more LC network circuits. This can be done to cover a wider bandwidth and/or so that each LC network circuit covers a narrower bandwidth (e.g., it is more tuned to the second harmonics within a narrower bandwidth). The harmonic gate termination circuit 414b can be configured to cover a range of bandwidths expected to be seen by the Doherty PA architecture 400b. Each LC network circuit of the harmonic gate termination circuit 414b can be tuned to a range of frequencies which, when aggregated, cover the entire range of frequencies expected to be seen by the Doherty PA architecture 400b, similar to the Doherty PA architecture 400a with the double harmonic gate termination circuit 414a which includes exactly two LC network circuits.

Additional LC network circuits can increase the size and/or cost of the resulting device. Where space is at a premium, this may be disadvantageous. However, where space and cost are not driving factors, and where improving performance over wider bandwidths is desirable, additional LC network circuits can be implemented as illustrated in FIG. 4B. In some implementations, the addition of more harmonic trapping may affect other performance metrics. For example, where the bandwidth range covers 3.3 GHZ to 3.8 GHZ (the frequency range of 6.6 GHz to 7.6 GHz being the second harmonic), adding more harmonic trapping may degrade performance at the higher end frequencies because the additional LC network circuits may increase insertion loss.

### Performance of Harmonic Termination Circuits

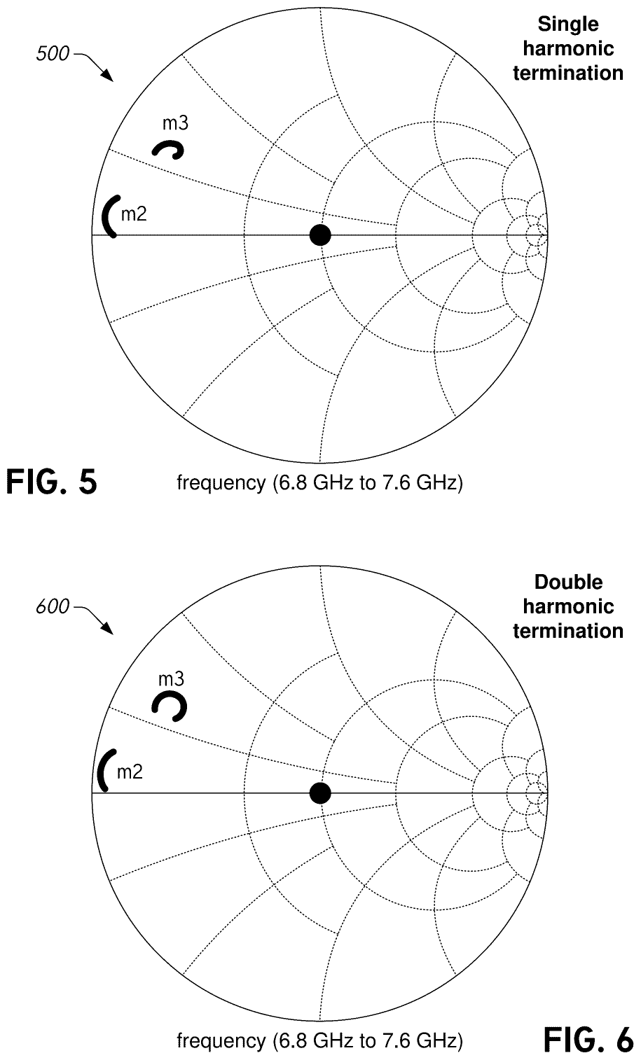

FIGS. 5, 6, and 7 illustrate differences between single harmonic termination and double harmonic termination. These differences manifest themselves primarily in the bandwidth response. Thus, FIG. 5 illustrates a Smith chart 500 of the reflection coefficients at the base of the transistor Q1 over the frequency range 6.8 GHz to 7.6 GHz for the single harmonic termination and FIG. 6 illustrates a Smith chart 600 over this same frequency range for the reflection coefficients for the double harmonic termination. In the Smith charts 500, 600, m2 refers to the second harmonic impedance at the base and m3 refers to the second harmonic impedance at the first impedance matching network 212 (with reference to FIGS. 2-4B).

Referring to FIG. 5, the termination of the second harmonic impedance exhibits a narrow band response wherein the real impedance of the second harmonic of the center band frequency is greater than 1 Ohm. For example, at 7.2 GHZ, the impedance of m2 is 1.66 for the single harmonic termination (FIG. 5) and 0.95 for the double harmonic termination (FIG. 6). This shows that the double harmonic termination acts as a superior short for the frequencies in question compared to the single harmonic termination. That is, double harmonic termination displays a wideband response in FIG. 6 wherein the impedance of the second harmonic (m2) of the center band (7.2 GHZ) is less than 1 ohm.

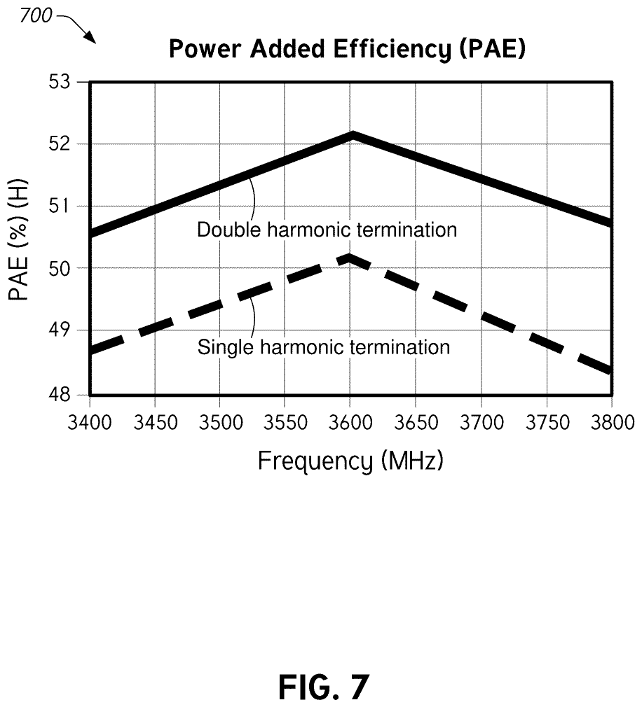

FIG. 7 illustrates a graph 700 of the PAE of the single harmonic termination (dashed line) and the double harmonic termination (solid line). This graph shows an increase in PAE of more than 1% for the double harmonic termination compared to single harmonic termination.

### Examples of Products and Architectures

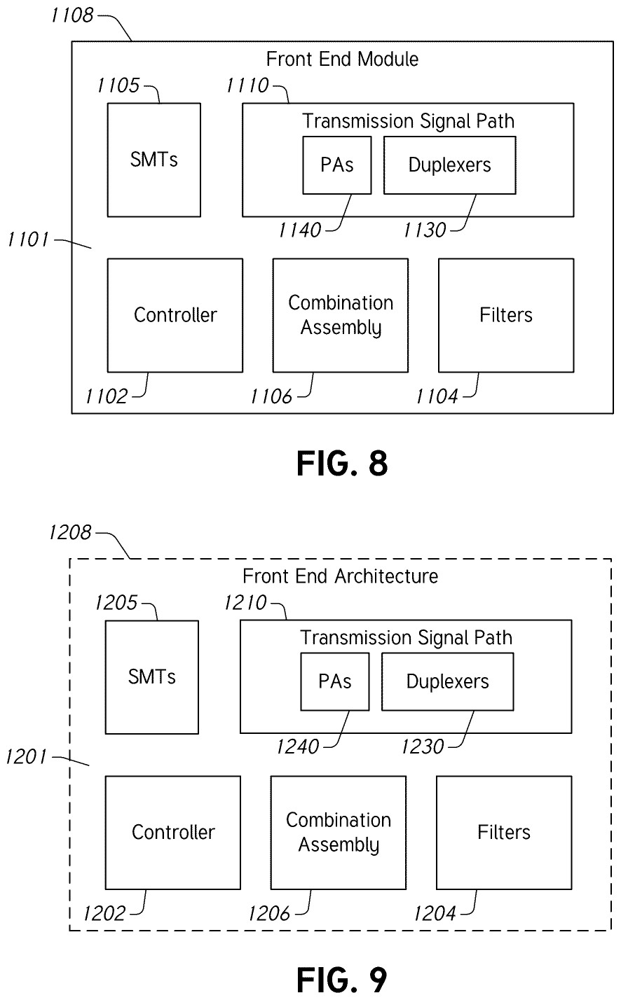

FIG. 8 illustrates that, in some embodiments, some or all of the front end configurations, including some or all of the Doherty PA configurations having combinations of features (e.g., FIGS. 1, 2, 4A, and 4B), can be implemented, wholly or partially, in a module. Such a module can be, for example, a front end module (FEM). Such a module can be, for example, a diversity receiver (DRx) FEM. Such a module can be, for example, a multi-input, multi-output (MiMo) module.

In the example of FIG. 8, a module 1108 can include a packaging substrate 1101, and a number of components can be mounted on such a packaging substrate 1101. For example, a controller 1102 (which may include a front end power management integrated circuit [FE-PIMC]), a combination assembly 1106, a transmission signal path 1110 that includes one or more duplexers 1130 and one or more amplifiers 1140 (e.g., PAs), the one or more amplifiers 1140 being configured as described herein to improve PAE performance using a broad harmonic termination circuit. A filter bank 1104 (which may include one or more multiplexers) can be mounted and/or implemented on and/or within the packaging substrate 1101. Other components, such as a number of SMT devices 1105, can also be mounted on the packaging substrate 1101. Although all of the various components are depicted as being laid out on the packaging substrate 1101, it will be understood that some component(s) can be implemented over other component(s).

In some embodiments, the transmission signal path 1110 can be implemented on a semiconductor die that is in turn mounted on the packaging substrate 1101. In further embodiments, the duplexers 1130 and/or the PAs 1140 can be implemented on a single semiconductor die that is mounted on the packaging substrate 1101. In various embodiments, one or more of the plurality of duplexers 1130 or the PAs 1140 are implemented on a semiconductor die with one or more of the other components mounted on a separate semiconductor die or on the packaging substrate 1101.

FIG. 9 shows that, in some embodiments, some or all of the front end configurations, including some or all of the Doherty PA configurations having combinations of features (e.g., FIGS. 1, 2, 4A, and 4B), can be implemented, wholly or partially, in an architecture. Such an architecture may include one or more modules, and can be configured to provide front end functionality.

In the example of FIG. 9, an architecture 1208 can include a controller 1202 (which may include a front end power management integrated circuit [FE-PIMC]), a combination assembly 1206, a transmission signal path 1210 that includes one or more duplexers 1230 and one or more amplifiers 1240 (e.g., PAs), the one or more amplifiers 1240 being configured as described herein to improve PAE performance using a broad harmonic termination circuit. A filter bank 1204 (which may include one or more multiplexers) can be mounted and/or implemented on and/or within the packaging substrate 1201. Other components, such as a number of SMT devices 1205, can also be implemented in the architecture 1208.

In some implementations, a device and/or a circuit having one or more features described herein can be included in an RF electronic device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

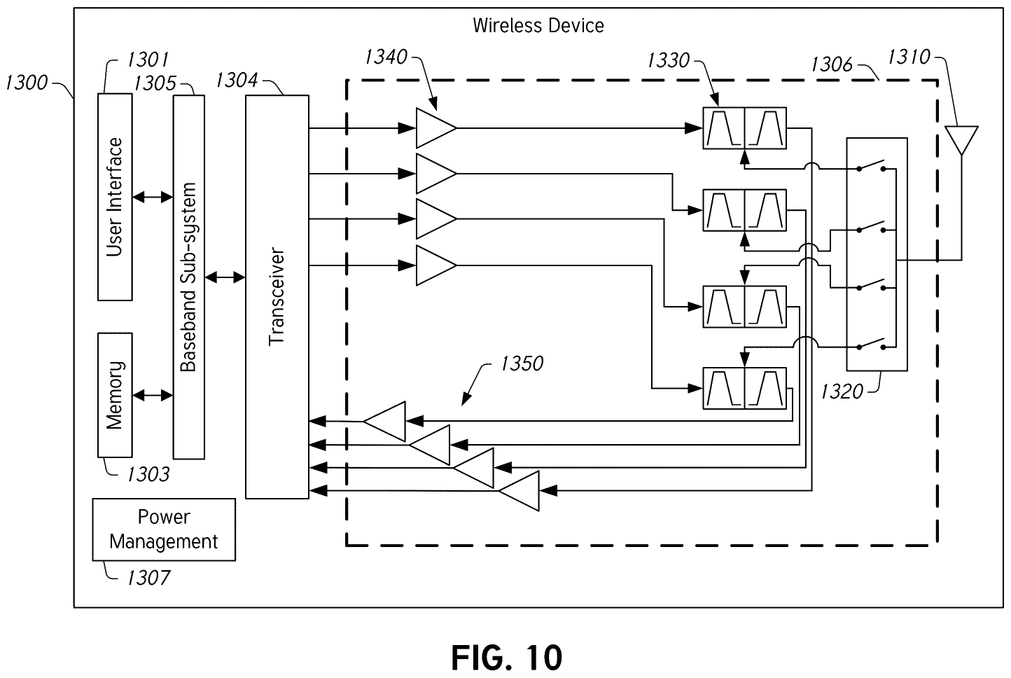

FIG. 10 depicts an example wireless device 1300 having one or more advantageous features described herein. In the context of one or more modules having one or more features as described herein, such modules can be generally depicted by a dashed box (e.g., a module 1306 which can be implemented as, for example, a front end module).

Referring to FIG. 10, power amplifiers 1340 (PAS) can receive their respective RF signals from a transceiver 1304 that can be configured and operated to generate RF signals to be amplified and transmitted, and to process received signals. The transceiver 1304 is shown to interact with a baseband sub-system 1305 that is configured to provide conversion between data and/or voice signals suitable for a user and RF signals suitable for the transceiver 1304. The transceiver 1304 can also be in communication with a power management component 1307 that is configured to manage power for the operation of the wireless device 1300. Such power management can also control operations of the baseband sub-system 1305 and the module 1306.

The baseband sub-system 1305 is shown to be connected to a user interface 1301 to facilitate various input and output of voice and/or data provided to and received from the user. The baseband sub-system 1305 can also be connected to a memory 1303 that is configured to store data and/or instructions to facilitate the operation of the wireless device, and/or to provide storage of information for the user.

In the example wireless device 1300, outputs of the PAs 1340 are routed to their respective duplexers 1330. Such amplified and filtered signals can be routed to a primary antenna 1310 through an antenna switch module 1320 (ASM) for transmission. The PAs 1340 can implement broad harmonic termination circuits to provide the advantages described herein.

Received signals are routed from the primary antenna 1310, through the ASM 1320, through the duplexers 1330, to the amplifiers 1350 (e.g., LNAs). For clarity, impedance matching components are not illustrated but are to be understood as being present along the transmission and receive paths as described herein.

One or more features of the present disclosure can be implemented with various cellular frequency bands as described herein. Examples of such bands are listed in Table 1. It will be understood that at least some of the bands can be divided into sub-bands. It will also be understood that one or more features of the present disclosure can be implemented with frequency ranges that do not have designations such as the examples of Table 1. It is to be understood that the term radio frequency (RF) and radio frequency signals refers to signals that include at least the frequencies listed in Table 1.

TABLE 1

| | | TX Frequency | RX Frequency |
|---|---|---|---|
| Band | Mode | Range (MHz) | Range (MHz) |
| B1 | FDD | 1,920-1,980 | 2,110-2,110b |
| B2 | FDD | 1,850-1,910 | 1,930-1,990 |
| B3 | FDD | 1,710-1,785 | 1,805-1,880 |
| B4 | FDD | 1,710-1,755 | 2,110-2,155 |
| B5 | FDD | 824-849 | 869-894 |
| B6 | FDD | 830-840 | 875-885 |
| B7 | FDD | 2,500-2,570 | 2,620-2,690 |
| B8 | FDD | 880-915 | 925-960 |
| B9 | FDD | 1,749.9-1,784.9 | 1,844.9-1,879.9 |
| B10 | FDD | 1,710-1,770 | 2,110-2,110b |
| B11 | FDD | 1,427.9-1,447.9 | 1,475.9-1,495.9 |
| B12 | FDD | 699-716 | 729-746 |
| B13 | FDD | 777-787 | 746-756 |
| B14 | FDD | 788-798 | 758-768 |
| B15 | FDD | 1,900-1,920 | 2,600-2,620 |
| B16 | FDD | 2,010-2,025 | 2,585-2,600 |
| B17 | FDD | 704-716 | 734-746 |
| B18 | FDD | 815-830 | 860-875 |
| B19 | FDD | 830- 845 | 875-890 |
| B20 | FDD | 832-862 | 791-821 |
| B21 | FDD | 1,447.9-1,462.9 | 1,495.9-1,510.9 |
| B22 | FDD | 3,410-3,490 | 3,510-3,590 |
| B23 | FDD | 2,000-2,020 | 2,180-2,200 |
| B24 | FDD | 1,626.5-1,660.5 | 1,525-1,559 |
| B25 | FDD | 1,850-1,915 | 1,930-1,995 |
| B26 | FDD | 814-849 | 859-894 |
| B27 | FDD | 807-824 | 852-869 |
| B28 | FDD | 703-748 | 758-803 |
| B29 | FDD | N/A | 716-728 |
| B30 | FDD | 2,305-2,315 | 2,350-2,360 |
| B31 | FDD | 452.5-457.5 | 462.5-467.5 |
| B32 | FDD | N/A | 1,452-1,496 |
| B33 | TDD | 1,900-1,920 | 1,900-1,920 |
| B34 | TDD | 2,010-2,025 | 2,010-2,025 |
| B35 | TDD | 1,850-1,910 | 1,850-1,910 |
| B36 | TDD | 1,930-1,990 | 1,930-1,990 |
| B37 | TDD | 1,910-1,930 | 1,910-1,930 |
| B38 | TDD | 2,570-2,620 | 2,570-2,620 |
| B39 | TDD | 1,880-1,920 | 1,880-1,920 |
| B40 | TDD | 2,300-2,400 | 2,300-2,400 |
| B41 | TDD | 2,496-2,690 | 2,496-2,690 |
| B42 | TDD | 3,400-3,600 | 3,400-3,600 |
| B43 | TDD | 3,600-3,800 | 3,600-3,800 |
| B44 | TDD | 703-803 | 703-803 |
| B45 | TDD | 1,447-1,467 | 1,447-1,467 |
| B46 | TDD | 5,150-5,925 | 5,150-5,925 |
| B65 | FDD | 1,920-2,010 | 2,110-2,200 |
| B66 | FDD | 1,710-1,780 | 2,110-2,200 |
| B67 | FDD | N/A | 738-758 |
| B68 | FDD | 698-728 | 753-783 |
| B71 | FDD | 663-698 | 617-652 |

### Terminology and Additional Embodiments

The present disclosure describes various features, no single one of which is solely responsible for the benefits described herein. It will be understood that various features described herein may be combined, modified, or omitted, as would be apparent to one of ordinary skill. Other combinations and sub-combinations than those specifically described herein will be apparent to one of ordinary skill, and are intended to form a part of this disclosure. Various methods are described herein in connection with various flowchart steps and/or phases. It will be understood that in many cases, certain steps and/or phases may be combined together such that multiple steps and/or phases shown in the flowcharts can be performed as a single step and/or phase. Also, certain steps and/or phases can be broken into additional sub-components to be performed separately. In some instances, the order of the steps and/or phases can be rearranged and certain steps and/or phases may be omitted entirely. Also, the methods described herein are to be understood to be open-ended, such that additional steps and/or phases to those shown and described herein can also be performed.

Some aspects of the systems and methods described herein can advantageously be implemented using, for example, computer software, hardware, firmware, or any combination of computer software, hardware, and firmware. Computer software can comprise computer executable code stored in a computer readable medium (e.g., non-transitory computer readable medium) that, when executed, performs the functions described herein. In some embodiments, computer-executable code is executed by one or more general purpose computer processors. A skilled artisan will appreciate, in light of this disclosure, that any feature or function that can be implemented using software to be executed on a general purpose computer can also be implemented using a different combination of hardware, software, or firmware. For example, such a module can be implemented completely in hardware using a combination of integrated circuits. Alternatively or additionally, such a feature or function can be implemented completely or partially using specialized computers designed to perform the particular functions described herein rather than by general purpose computers.

Multiple distributed computing devices can be substituted for any one computing device described herein. In such distributed embodiments, the functions of the one computing device are distributed (e.g., over a network) such that some functions are performed on each of the distributed computing devices.

Some embodiments may be described with reference to equations, algorithms, and/or flowchart illustrations. These methods may be implemented using computer program instructions executable on one or more computers. These methods may also be implemented as computer program products either separately, or as a component of an apparatus or system. In this regard, each equation, algorithm, block, or step of a flowchart, and combinations thereof, may be implemented by hardware, firmware, and/or software including one or more computer program instructions embodied in computer-readable program code logic. As will be appreciated, any such computer program instructions may be loaded onto one or more computers, including without limitation a general purpose computer or special purpose computer, or other programmable processing apparatus to produce a machine, such that the computer program instructions which execute on the computer(s) or other programmable processing device(s) implement the functions specified in the equations, algorithms, and/or flowcharts. It will also be understood that each equation, algorithm, and/or block in flowchart illustrations, and combinations thereof, may be implemented by special purpose hardware-based computer systems which perform the specified functions or steps, or combinations of special purpose hardware and computer-readable program code logic means.

Furthermore, computer program instructions, such as embodied in computer-readable program code logic, may also be stored in a computer readable memory (e.g., a non-transitory computer readable medium) that can direct one or more computers or other programmable processing devices to function in a particular manner, such that the instructions stored in the computer-readable memory implement the function(s) specified in the block(s) of the flowchart(s). The computer program instructions may also be loaded onto one or more computers or other programmable computing devices to cause a series of operational steps to be performed on the one or more computers or other programmable computing devices to produce a computer-implemented process such that the instructions which execute on the computer or other programmable processing apparatus provide steps for implementing the functions specified in the equation(s), algorithm(s), and/or block(s) of the flowchart(s).

Some or all of the methods and tasks described herein may be performed and fully automated by a computer system. The computer system may, in some cases, include multiple distinct computers or computing devices (e.g., physical servers, workstations, storage arrays, etc.) that communicate and interoperate over a network to perform the described functions. Each such computing device typically includes a processor (or multiple processors) that executes program instructions or modules stored in a memory or other non-transitory computer-readable storage medium or device. The various functions disclosed herein may be embodied in such program instructions, although some or all of the disclosed functions may alternatively be implemented in application-specific circuitry (e.g., ASICs or FPGAs) of the computer system. Where the computer system includes multiple computing devices, these devices may, but need not, be co-located. The results of the disclosed methods and tasks may be persistently stored by transforming physical storage devices, such as solid state memory chips and/or magnetic disks, into a different state.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list. The word “exemplary” is used exclusively herein to mean “serving as an example, instance, or illustration.” Any implementation described herein as “exemplary” is not necessarily to be construed as preferred or advantageous over other implementations.

The disclosure is not intended to be limited to the implementations shown herein. Various modifications to the implementations described in this disclosure may be readily apparent to those skilled in the art, and the generic principles defined herein may be applied to other implementations without departing from the spirit or scope of this disclosure. The teachings of the invention provided herein can be applied to other methods and systems, and are not limited to the methods and systems described above, and elements and acts of the various embodiments described above can be combined to provide further embodiments. Accordingly, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A Doherty power amplifier for amplifying radio-frequency (RF) signals with an input frequency range corresponding to a system bandwidth, the Doherty power amplifier comprising:
a power splitter configured to receive an input signal and to provide a first signal associated with the input signal on a carrier amplification path and a second signal associated with the input signal on a peaking amplification path;
a first impedance matching network implemented on the carrier amplification path;
a carrier amplifier implemented on the carrier amplification path;
a double harmonic termination circuit implemented on the carrier amplification path between the first impedance matching network and the carrier amplifier, the double harmonic termination circuit configured to short a range of second harmonics for the system bandwidth; and
a peaking amplifier implemented on the peaking amplification path.

2. The Doherty power amplifier of claim 1, wherein the system bandwidth is greater than or equal to 400 MHZ.

3. The Doherty power amplifier of claim 1, wherein the double harmonic termination circuit includes exactly two LC network circuits in parallel.

4. The Doherty power amplifier of claim 3, further including a common mode ground inductor coupled in series between the two LC network circuits and a reference potential node.

5. The Doherty power amplifier of claim 3, wherein a first LC network circuit of the two LC network circuits is configured to resonate between a second harmonic frequency of a low end frequency of the input frequency range and a second harmonic frequency of a center band frequency of the input frequency range.

6. The Doherty power amplifier of claim 5, wherein a second LC network circuit of the two LC network circuits is configured to resonate between the second harmonic frequency of the center band frequency and a second harmonic frequency of a high end frequency of the input frequency range.

7. The Doherty power amplifier of claim 1, wherein the double harmonic termination circuit includes more than two LC network circuits in parallel.

8. The Doherty power amplifier of claim 1 further comprising a second impedance matching network implemented on the peaking amplification path between the power splitter and the peaking amplifier.

9. The Doherty power amplifier of claim 1, wherein the carrier amplifier comprises a transistor.

10. The Doherty power amplifier of claim 9, wherein the double harmonic termination circuit is coupled between a base of the transistor and a reference potential node.

11. A front end module comprising:
a packaging substrate; and
a Doherty power amplifier implemented on the packaging substrate, the Doherty power amplifier configured to amplify radio-frequency (RF) signals in an input frequency range corresponding to a system bandwidth, the Doherty power amplifier including: a power splitter configured to receive an input signal and to provide a first signal associated with the input signal on a carrier amplification path and a second signal associated with the input signal on a peaking amplification path; a first impedance matching network implemented on the carrier amplification path; a carrier amplifier implemented on the carrier amplification path; a double harmonic termination circuit implemented on the carrier amplification path between the first impedance matching network and the carrier amplifier, the double harmonic termination circuit configured to short a range of second harmonics for the input frequency range; and a peaking amplifier implemented on the peaking amplification path.

12. The front end module of claim 11, wherein the system bandwidth is greater than or equal to 400 MHZ.

13. The front end module of claim 11, wherein the double harmonic termination circuit includes exactly two LC network circuits in parallel.

14. The front end module of claim 13, further including a common mode ground inductor coupled in series between the two LC network circuits and a reference potential node.

15. The front end module of claim 13, wherein a first LC network circuit of the two LC network circuits is configured to resonate between a second harmonic frequency of a low end frequency of the input frequency range and a second harmonic frequency of a center band frequency of the input frequency range.

16. The front end module of claim 15, wherein a second LC network circuit of the two LC network circuits is configured to resonate between the second harmonic frequency of the center band frequency and a second harmonic frequency of a high end frequency of the input frequency range.

17. The front end module of claim 11, wherein the double harmonic termination circuit includes more than two LC network circuits in parallel.

18. The front end module of claim 11 further comprising a second impedance matching network implemented on the peaking amplification path between the power splitter and the peaking amplifier.

19. The front end module of claim 11, wherein the carrier amplifier comprises a transistor and the double harmonic termination circuit is coupled between a base of the transistor and a reference potential node.

20. A wireless device comprising:
a primary antenna; and
a front end module coupled to the primary antenna, the front end module comprising a Doherty power amplifier configured to amplify radio-frequency (RF) signals in an input frequency range corresponding to a system bandwidth, the Doherty power amplifier including: a power splitter configured to receive an input signal and to provide a first signal associated with the input signal on a carrier amplification path and a second signal associated with the input signal on a peaking amplification path; a first impedance matching network implemented on the carrier amplification path; a carrier amplifier implemented on the carrier amplification path; a double harmonic termination circuit implemented on the carrier amplification path between the first impedance matching network and the carrier amplifier, the double harmonic termination circuit configured to short a range of second harmonics for the input frequency range; and a peaking amplifier implemented on the peaking amplification path.
